(19) United States
(12) Patent Application Publication
(10) Pub. No.: US 2026/0150367 A1
(43) Pub. Date: May 28, 2026

(54) SEMICONDUCTOR DEVICE

(71) Applicant: Vanguard International Semiconductor Corporation, Hsinchu (TW)

(72) Inventors: Yi-Wei LIEN, Hsinchu (TW); Wei-Chih CHENG, Tainan City (TW); Hsin-Chang TSAI, Kaohsiung City (TW); Hao-Ching HSU, Xihu Township (TW)

(73) Assignee: Vanguard International Semiconductor Corporation, Hsinchu (TW)

(21) Appl. No.: 18/958,971

(22) Filed: Nov. 25, 2024

(51) Int. Cl. H01L 29/40; H01L 29/08; H01L 29/778

(52) U.S. Cl. CPC H10D 64/112; H10D 30/475; H10D 62/151

(57) ABSTRACT

A semiconductor device is provided. The semiconductor device includes a substrate, a gate structure, a first interlayer dielectric layer, a source structure, a drain structure, a dielectric pattern, and first and second field plates. The gate structure is disposed on the substrate. The first interlayer dielectric layer is disposed on the substrate and partially covers the gate structure. The source structure and the drain structure are disposed on the substrate and are located on opposite sides of the gate structure. The dielectric pattern is disposed on the first interlayer dielectric layer between the gate structure and the drain structure. The first field plate covers the dielectric pattern, as well as covering the first interlayer dielectric layer between the gate structure and the dielectric pattern. The second field plate is disposed above the first field plate and the dielectric pattern and extends toward the drain structure.

### BACKGROUND OF THE INVENTION

### Field of the Invention

The present disclosure relates to a semiconductor device, and, in particular, to a high electron mobility transistor device.

### Description of the Related Art

High electron mobility transistors, also called heterostructure FETs (HFETs) or modulation-doped FETs (MODFETs), are field effect transistors composed of semiconductor materials with different energy gaps. A two-dimensional electron gas (2DEG) layer is generated at the interface between different semiconductor materials that are adjacent. Due to the high electron mobility of two-dimensional electron gas, high electron mobility transistor devices have the advantages of high breakdown voltage, high electron mobility, low on-resistance, and low input capacitance, and are therefore suitable for use in high-power components.

However, although existing high electron mobility transistor devices are generally suitable for their intended purposes, they have not been entirely satisfactory in all respects. Therefore, there is a need to further improve high electron mobility transistor devices and methods for forming the same to improve performance and reliability.

### BRIEF SUMMARY OF THE INVENTION

An embodiment of the disclosure provides a semiconductor device. The semiconductor device includes a substrate, a gate structure, a first interlayer dielectric layer, a source structure, a drain structure, a dielectric pattern, a first field plate and a second field plate. The gate structure is disposed on the substrate. The first interlayer dielectric layer is disposed on the substrate and partially covers the gate structure. The source structure and the drain structure are disposed on the substrate and located on opposite sides of the gate structure. The dielectric pattern is disposed on the first interlayer dielectric layer between the gate structure and the drain structure. The first field plate is disposed on the substrate and covering the dielectric pattern, as well as covering the first interlayer dielectric layer between the gate structure and the dielectric pattern. The second field plate is disposed above the first field plate and the dielectric pattern and extends toward the drain structure.

### BRIEF DESCRIPTION OF THE DRAWINGS

The present invention can be more fully understood by reading the subsequent detailed description and examples with references made to the accompanying drawings, wherein:

FIG. 1 is a schematic cross-sectional view of a semiconductor device in accordance with some embodiments of the disclosure; and

FIG. 2 is a schematic cross-sectional view of a semiconductor device in accordance with some embodiments of the disclosure.

### DETAILED DESCRIPTION OF THE INVENTION

The embodiments of the present disclosure are described fully hereinafter with reference to the accompanying drawings. It should be noted, however, that the present disclosure is not limited to the following exemplary embodiments, and may be implemented in various forms. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the disclosure.

The following disclosure provides various embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

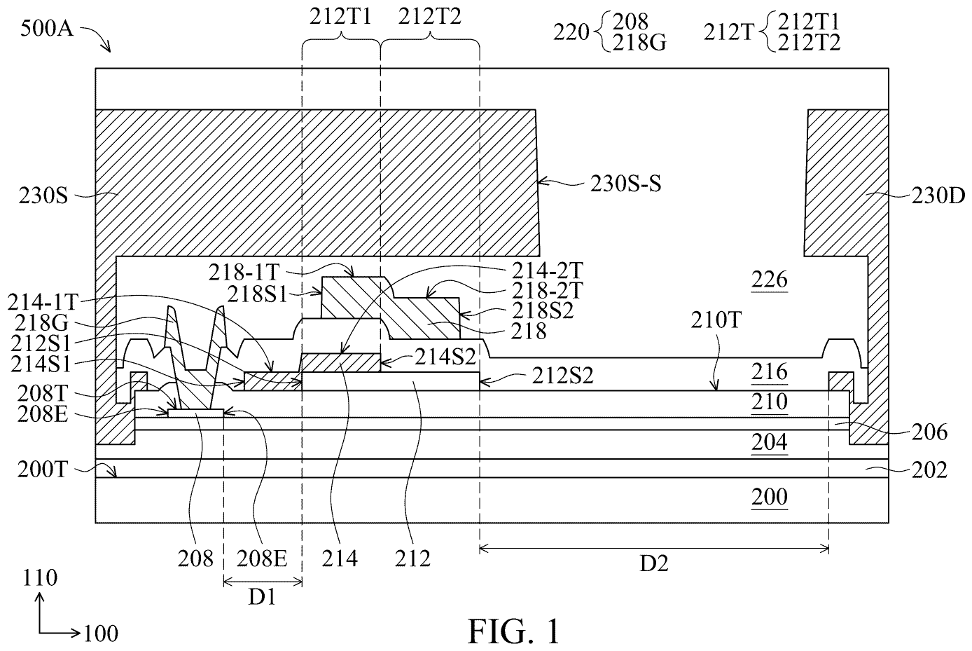

FIG. 1 is a schematic cross-sectional view of a semiconductor device 500A in accordance with some embodiments of the disclosure. In some embodiments, the semiconductor device 500A includes a high electron mobility transistor (HEMT), such as a gallium nitride-based enhancement-mode high electron mobility transistor (E-mode GaN HEMT). As shown in FIG. 1, the semiconductor device 500A includes a substrate 200, a gate structure 220, an interlayer dielectric layer 210, a dielectric pattern 212, a first field plate 214 and a second field plate 218.

In some embodiments, the substrate 200 includes an elementary semiconductor including silicon (Si) or germanium (Ge); a compound semiconductor including gallium arsenide (GaAs), gallium phosphide (GaP), indium phosphide (InP), indium arsenide (InAs) and/or indium antimonide (InSb); an alloy semiconductor including SiGe, GaAsP, AlInAs, AlGaAs, GaInAs, GaInP, and/or GaInAsP, or a combination thereof.

In some embodiments, the substrate 200 may be a semiconductor on insulator substrate, such as a silicon on insulator (SOI) substrate or a silicon germanium on insulator (SGOI) substrate. In other embodiments, the substrate 200 may be a ceramic substrate, such as an aluminum nitride (AlN) substrate, a silicon carbide (SiC) substrate, an aluminum oxide (Al₂O₃) substrate (or called a sapphire (sapphire) substrate), a glass substrate, or other similar substrates. In some embodiments, the substrate 200 may include a ceramic substrate and a pair of blocking layers respectively disposed on upper and lower surfaces of the ceramic substrate. The ceramic substrate may include a ceramic material, and the ceramic material may include a metal-inorganic material. For example, the ceramic substrate may include silicon carbide (SiC), aluminum nitride (AlN), sapphire substrate, or other suitable materials. The sapphire substrate may be aluminum oxide. In some embodiments, the blocking layers located on the top and bottom surfaces of the ceramic substrate may include a single layer or multiple layers of insulating material and/or other suitable material layers, such as semiconductor layers. The insulating material layer may be oxide, nitride, oxynitride, or other suitable insulating materials. The semiconductor layer may be polysilicon. The blocking layer may be capable of preventing the diffusion of the ceramic substrate. The blocking layer may also prevent the ceramic substrate from interacting with other film layers or processing tools. In some embodiments, the blocking layer may also encapsulate the ceramic substrate. At this time, the barrier layer may not only cover the top and bottom surfaces of the ceramic substrate, but also cover both side surfaces of the ceramic substrate.

In some embodiment, the semiconductor device 500A further includes a buffer layer 202. As shown in FIG. 1, the buffer layer 202 is located on the top surface 200T of the substrate 200. Since the crystal lattice and the coefficient of thermal expansion of the substrate 200 may be different from those of the features (such as a channel layer 204) above the substrate 200, strains may occur at or near the interface between the substrate 200 and the features above the substrate 200, resulting in defects such as cracks or warpage. Therefore, the buffer layer 202 on the substrate 200 can relief the strains in the features formed above the buffer layer 202 (e.g., the channel layer 204), preventing defects from forming in the above features. In some embodiments, the material of the buffer layer 202 may include III-V compound semiconductor materials, such as III-nitride. For example, the material of the buffer layer 202 may include: aluminum nitride (AlN), gallium nitride (GaN), aluminum gallium nitride (AlₓGa₁₋ₓN, where 0<x<1), aluminum nitride Indium (AlInN), a combination of thereof, or other similar materials. In some embodiments, the buffer layer 202 may be formed by an epitaxial growth process, such as metal organic chemical vapor deposition (MOCVD), hydride vapor phase epitaxy (HVPE), molecular beam epitaxy (MBE), other suitable methods, or a combination of thereof. In some embodiments, the buffer layer 202 may be a multi-layer structure (not shown). For example, the buffer layer 202 may include a superlattice buffer layer and/or a gradient buffer layer. The superlattice buffer layer may be disposed on the substrate 200, and the gradient buffer layer is disposed on the superlattice buffer layer. The buffer layer 202 may effectively prevent dislocations in the substrate 200 from entering the features above the substrate 200. The buffer layer 202 may further improve the crystallization quality of other overlying films and/or layers.

In some embodiments, the semiconductor device 500A may optionally include a seed layer (not shown) between the substrate 200 and the buffer layer 202. The seed layer can relieve the lattice difference between the substrate 200 and the films and/or layers growing thereon, so as to improve the crystallization quality. In some embodiments, the material of the seed layer may include aluminum nitride (AlN), aluminum gallium nitride (AlGaN), other suitable materials, or a combination of thereof. In some embodiments, the seed layer of a single-layer or multi-layer structure may be formed by, for example, chemical vapor deposition (CVD), atomic layer deposition (ALD), physical vapor deposition (PVD), other suitable processes, or a combination of thereof.

In some embodiments, the semiconductor device 500A further includes the channel layer 204. As shown in FIG. 1, the channel layer 204 is located on the buffer layer 202. In some embodiments, the material of the channel layer 204 includes a binary compound semiconductor of group III-V, such as group-III nitride. For example, the material of the channel layer 204 includes gallium nitride (GaN). In some embodiments, the channel layer 204 may be doped with n-type dopants or p-type dopants. In some embodiments, the channel layer 204 may be formed by an epitaxial growth process, such as metal organic chemical vapor deposition (MOCVD), hydride vapor phase epitaxy (HVPE), molecular beam epitaxy (MBE), liquid phase epitaxy (LPE), other suitable processes, or a combination of thereof.

In some embodiments, the semiconductor device 500A further includes a barrier layer 206. As shown in FIG. 1, the barrier layer 206 is located on the channel layer 204. The material of the barrier layer 206 may include a ternary compound semiconductor of group III-V, such as group-III nitride. For example, the material of the barrier layer 206 may be aluminum gallium nitride (Al_{y}Ga_{1-y}N, where 0<y<1), aluminum indium nitride (AlInN), or a combination thereof. In other embodiments, the barrier layer 206 may also include gallium nitride (GaN), aluminum nitride (AlN), gallium arsenide (GaAs), gallium indium phosphide (GaInP), aluminum gallium arsenide (AlGaAs), indium phosphide (InP), indium aluminum arsenide (InAlAs), indium gallium arsenide (InGaAs), other suitable III-V materials, or a combination of thereof. In some embodiments, the barrier layer 206 may be doped with n-type dopants or p-type dopants. In some embodiments, the barrier layer 206 may be formed by an epitaxial growth process, such as metal organic chemical vapor deposition (MOCVD), hydride vapor phase epitaxy (HVPE), molecular beam epitaxy (MBE), liquid phase epitaxy (LPE), other suitable processes, or a combination of thereof.

According to some embodiments of the disclosure, the channel layer 204 and the barrier layer 206 include different materials, and the interface between the channel layer 204 and the barrier layer 206 is a heterojunction structure. The lattice mismatch between the channel layer 204 and barrier layer 206 may result in stress that leads to piezoelectric polarization effect. In addition, the ionicity of the bonding between the group-III metals (such as aluminum (Al), gallium (Ga), or indium (In)) and nitrogen bonding is relatively strong, thereby resulting in spontaneous polarization. Due to the difference in energy gap between the heterogeneous materials of the channel layer 204 and the barrier layer 206 and the aforementioned piezoelectric polarization and spontaneous polarization effects, two-dimensional electron gas (2DEG) (not shown) is formed at the heterogeneous interface between the channel layer 204 and the barrier layer 206. In some embodiments, the two-dimensional electron gas is used as the conductive carriers of the semiconductor device 500A.

The gate structure 220 is disposed on the barrier layer 206 and covers a portion of the barrier layer 206. In some embodiments, the gate structure 220 includes a gate layer 208 and a gate electrode layer 218G.

The gate layer 208 is located on a portion of the barrier layer 206 and is in contact with the barrier layer 206. As shown in FIG. 1, the gate layer 208 may have a rectangular cross section as shown in FIG. 1. In addition, the cross section of the gate layer 208 may also be in other shapes, such as a trapezoidal cross section. In some embodiments, the material of the gate layer 208 may include n-type or p-type doped III-V semiconductors, such as: gallium nitride (GaN), aluminum gallium nitride (AlGaN), aluminum nitride (AlN), arsenic gallium (GaAs), aluminum gallium arsenide (AlGaAs), indium phosphide (InP), aluminum indium arsenide (InAlAs), indium gallium arsenide (InGaAs), or other III-V semiconductors. In other embodiments, the gate layer 208 includes p-type doped II-VI semiconductors, such as cadmium sulfide (CdS), cadmium telluride (CdTe), zinc sulfide (ZnS), or other II-VI semiconductors. In some embodiments, the gate layer 208 is formed by metal organic chemical vapor deposition (MOCVD), hydride vapor phase epitaxy (HVPE), molecular beam epitaxy (MBE), a combination of thereof, or other suitable methods and subsequent patterning process. In this embodiment, the gate layer 208 may be doped. For example, the dopants may include magnesium (Mg), zinc (Zn), calcium (Ca), beryllium (Be), strontium (Sr), barium (Ba), radium (Ra), carbon (C), silver (Ag), gold (Au), lithium (Li) or sodium (Na), so that the conductivity type of the gate layer 208 is p-type.

The gate electrode layer 218G is located on gate layer 208. The gate electrode layer 218G is in contact with and partially covers the top surface 208T of gate layer 208. In some embodiments, the material of the gate electrode layer 218G may include a single-layer or multi-layer structure formed by metal, metal nitride, metal oxide, metal alloy, other suitable conductive materials, or a combination of thereof, or a combination of thereof. The metals may include, for example, gold (Au), nickel (Ni), platinum (Pt), palladium (Pd), iridium (Ir), titanium (Ti), chromium (Cr), tungsten (W), aluminum (Al), copper (Cu), similar materials, an alloy thereof, or a combination thereof. The metal alloy may include titanium tungsten (TiW). The metal nitrides may include molybdenum nitride (MoN), tungsten nitride (WN), titanium nitride (TiN), tantalum nitride (TaN), tantalum silicon nitride (TaSiN), tantalum carbide nitride (TaCN), nitrogen aluminum titanium (TiAlN), or other similar materials. In other embodiments, the conductive material of the gate electrode layer 218G may include nickel silicide (NiSi), cobalt silicide (CoSi), tantalum carbide (TaC), titanium aluminide (TiAl), or other similar materials. In this embodiment, the gate electrode layer 218G is titanium nitride (TiN).

In some embodiments, the gate electrode layer 218G may be formed by a deposition process followed by a patterning process. For example, the deposition process may include chemical vapor deposition (CVD), atomic layer deposition (ALD), or physical vapor deposition (PVD) such as sputtering or evaporation.

As shown in FIG. 1, the semiconductor device 500A further includes an interlayer dielectric layer 210 disposed on the barrier layer 206. Furthermore, the interlayer dielectric layer 210 partially covers the gate structure 220. As shown in FIG. 1, the interlayer dielectric layer 210 is in contact with opposite side surfaces (not shown) of the gate layer 208, a portion of the top surface 208T of the gate layer 208, a portion of side surfaces of the gate electrode layer 218G, and the barrier layer 206 that is not covered by the gate structure 220.

In some embodiments, the interlayer dielectric layer 210 may be a single-layer structure or a multi-layer structure. In this embodiment, the interlayer dielectric layer 210 may be a single-layer structure or a multi-layer structure formed of the same material.

In some embodiments, the interlayer dielectric layer 210 may include dielectric materials such as silicon oxide, silicon nitride, silicon oxynitride, tetraethoxysilane (TEOS) oxide, phosphosilicate glass (PSG), borosilicate glass (BSG), borophosphosilicate glass (BPSG), undoped silicate glass (USG), fluorinated silicate glass (FSG), organosilicate glasses (OSG), low-k dielectric materials, and/or other suitable dielectric materials, or a combination of thereof. The low-k dielectric materials may include (but not limited to) fluorinated silica glass (FSG), hydrogen silsesquioxane (HSQ), carbon-doped silicon oxide, amorphous fluorinated carbon, parylene, bis-benzocyclobutene (BCB), polyimide, or a combination thereof. In some embodiments, the interlayer dielectric layer 210 may be formed by a deposition process. For example, the deposition process may include spin-on coating, chemical vapor deposition (CVD), atomic layer deposition (ALD), low-pressure chemical vapor deposition (LPCVD), high-density plasma chemical vapor deposition (HDPCVD), other suitable processes, or a combination of thereof.

As shown in FIG. 1, the source structure 230S and the drain structure 230D are disposed on the substrate 200. The source structure 230S and the drain structure 230D are located on opposite sides of the gate structure 220 and opposite sides of the interlayer dielectric layer 210 in a direction 100 that is substantially parallel to the top surface 200T of the substrate 200 (which can also be regarded as a lateral direction). Furthermore, the source structure 230S and the drain structure 230D located on both sides of the gate layer 208 are separated from the gate layer 208 by the interlayer dielectric layer 210 in the direction 100. In addition, the interlayer dielectric layer 210 extends between the source structure 230S and the drain structure 230D in the direction 100. The source structure 230S and the drain structure 230D respectively extend from above the interlayer dielectric layer 210 into a portion of the channel layer 204 along a direction 110 that is substantially perpendicular to the top surface 200T of the substrate 200 (which can also be regarded as a vertical direction) and are in contact with the channel layer 204.

In some embodiments, the source structure 230S may be a composite structure (a multi-layer structure), which may include a source electrode layer (not shown), a source contact feature (not shown), and a source metal layer (not shown) in sequence from bottom to top. The source electrode layer is disposed on the barrier layer 206 and extends in the direction 100 to cover a portion of the top surface 210T of the interlayer dielectric layer 210. The source contact feature is located on the source electrode layer and extends in the direction 110. The source metal layer is located on the source contact feature and extends in the direction 100 toward the drain structure 230D. In some embodiments, the source metal layer completely covers the source electrode layer.

In some embodiments, the source electrode layer is conformally formed on the interlayer dielectric layer 210 and the barrier layer 206. In the cross-sectional view shown in FIG. 1, the source electrode layer has a stepped shape. In this embodiment, the number of steps of the stepped source electrode layer is 2. In addition, the source electrode layer may have two upper surfaces.

Similar to the source structure 230S, the drain structure 230D may be a composite structure (a multi-layer structure), which may include a drain electrode layer, a drain contact feature, and a drain metal layer in sequence from bottom to top. The drain electrode layer is disposed on the barrier layer 206 and extends in the direction 100 to cover a portion of the top surface 210T of the interlayer dielectric layer 210. The drain contact feature is located on the drain electrode layer and extends in the direction 110. The drain metal layer is located on the drain contact feature and extends in the direction 100. In some embodiments, the drain electrode layer and the source electrode layer are formed simultaneously. The drain contact feature and the source contact feature are formed simultaneously. In addition, the drain metal layer and the source metal layer 228S are formed simultaneously.

Similar to the source electrode layer, the drain electrode layer is conformally formed on the interlayer dielectric layer 210 and the barrier layer 206. In the cross-sectional view shown in FIG. 1, the drain electrode layer has a stepped shape. In this embodiment, the number of steps of the stepped drain electrode layer is 2. In addition, the drain electrode layer may have two upper surfaces.

The dielectric pattern 212 is disposed on a portion of the interlayer dielectric layer 210 between the gate structure 220 and the drain structure 230D. Furthermore, the dielectric pattern 212 covers a portion of the top surface 210T of the interlayer dielectric layer 210. The dielectric pattern 212 has a top surface 212T and opposite side surfaces 212S1 and 212S2 connected to the top surface 212T. The side surfaces 212S1 and 212S2 of the dielectric pattern 212 are both located on the top surface 210T of the interlayer dielectric layer 210. In the direction 110 that is substantially perpendicular to the top surface 200T of the substrate 200 (which can also be regarded as the vertical direction), the dielectric pattern 212 may partially overlap the interlayer dielectric layer 210. As shown in FIG. 1, in the direction 100 that is substantially parallel to the top surface 200T of the substrate 200 (which can also be regarded as the lateral direction), the side surface 212S1 of the dielectric pattern 212 is separated from the gate layer 208 of the gate structure 220 by a first distance D1. Furthermore, the side surface 212S2 of the dielectric pattern 212 is separated from the drain structure 230D (e.g., the drain electrode layer of the drain structure 230D) by a second distance D2. In some embodiments, the first distance D1 is less than the second distance D2. In other words, in the direction 100, the gate structure 220 is closer to the dielectric pattern 212 than the drain structure 230D.

In some embodiments, the dielectric pattern 212 may include dielectric materials, such as silicon oxide (SiO₂), silicon nitride (SiNₓ), silicon oxynitride (SiON), tetraethoxysilane (TEOS) oxide, phosphosilicate glass (PSG), borosilicate glass (BSG), borophosphosilicate glass (BPSG), undoped silicate glass (USG), fluorinated silicate glass (FSG), organosilicate glasses (OSG), and/or other suitable dielectric materials, or a combination thereof. In some embodiments, the dielectric pattern 212 may include a low-dielectric constant (low-k) dielectric material, a high-k dielectric material (the dielectric constant (k) of the high-k dielectric material is higher than the dielectric constant of silicon oxide (SiO₂) (k=3.9)), and/or other suitable dielectric materials, or a combination thereof. The low-k dielectric materials may include (but not limited to) fluorinated silica glass (FSG), hydrogen silsesquioxane (HSQ), carbon-doped silicon oxide, amorphous fluorinated carbon, parylene, bis-benzocyclobutene (BCB), polyimide, or a combination thereof. The high-k dielectric materials may include (but are not limited to) silicon nitride, hafnium oxide, hafnium silicon oxide, hafnium silicon oxynitride, hafnium tantalum oxide, hafnium titanium oxide, hafnium zirconium oxide, zirconium oxide, aluminum oxide, hafnium dioxide-alumina alloy, and/or a combination thereof or the like. In some embodiments, the dielectric pattern 212 may be a single-layer structure or a multi-layer structure formed of the above-mentioned dielectric materials.

In some embodiments, the dielectric constant of the interlayer dielectric layer 210 is the same as the dielectric constant of the dielectric pattern 212. For example, the interlayer dielectric layer 210 and the dielectric pattern 212 are both silicon dioxide and have the same dielectric constant (k=3.9). In some embodiments, the dielectric constant of the interlayer dielectric layer 210 is different from the dielectric constant of the dielectric pattern 212. The dielectric constant of the interlayer dielectric layer 210 may be smaller than the dielectric constant of the dielectric pattern 212. For example, the interlayer dielectric layer 210 is silicon dioxide (k=3.9), and the dielectric pattern 212 is silicon nitride (k=7.5).

In some embodiments, the dielectric pattern 212 may be formed by a deposition process and a subsequent patterning process. For example, the deposition process may include spin-on coating, chemical vapor deposition (CVD), atomic layer deposition (ALD), low pressure chemical vapor deposition (LPCVD), high density plasma chemical vapor deposition (HDPCVD), other suitable processes, or a combination thereof.

In some embodiments, when the dielectric pattern 212 is formed of a high-k dielectric material, such as silicon nitride, and the interlayer dielectric layer 210 is formed of silicon dioxide, the dielectric pattern 212 can withstand high electric fields. Therefore, the electric field distribution on the surface of the semiconductor device 500A can be relatively uniform. For example, the electric field peak at the edge of the subsequently formed field plate (for example, a side surface 214S2 of the first field plate 214 close to the drain structure 230D) can be reduced. In addition, since the interlayer dielectric layer 210 and the dielectric pattern 212 are formed of different dielectric materials, the interlayer dielectric layer 210 may serve as an etching stop layer for the dielectric pattern 212 during the patterning process (including lithography and etching processes) for forming the dielectric pattern 212. In addition, the thickness of the interlayer dielectric layer 210 is not affected by the etching process. Therefore, the figure of merit (FOM) of the semiconductor device 500A (for example, the pinch-off voltage of the semiconductor device 500A) can be further improved.

The first field plate 214 is disposed on the substrate 200. Furthermore, the first field plate 214 covers the interlayer dielectric layer 210 between the gate structure 220 and the dielectric pattern 212 and the dielectric pattern 212. As shown in FIG. 1, the first field plate 214 extends from the top surface 210T of the interlayer dielectric layer 210 to cover and contact the whole side surfaces 212S1 and a first portion 212T1 of the top surface 212T of the dielectric pattern 212 in the direction 100. In addition, a second portion 212T2 of the top surface 212T is exposed from the first field plate 214. In other words, the first field plate 214 does not extend to cover the side surface 212S2 of the dielectric pattern 212 close to the drain structure 230D, which can reduce the risk of a short circuit between the first field plate 214 and the drain structure 230D. Furthermore, the first portion 212T1 and the second portion 212T2 of the top surface 212T of the dielectric pattern 212 are adjacent to each other and are different portions of the top surface 212T of the dielectric pattern 212. For example, the first portion 212T1 of the top surface 212T of the dielectric pattern 212 is closer to the gate structure 220. In addition, the second portion 212T2 of the top surface 212T of the dielectric pattern 212 is closer to the drain structure 230D.

In some embodiments, the first field plate 214 is conformally formed on the interlayer dielectric layer 210 and the dielectric pattern 212. Therefore, the first field plate 214 has a stepped shape in the cross-sectional view shown in FIG. 1. In this embodiment, the number of steps of the stepped first field plate 214 is 2. Therefore, the first field plate 214 has two upper surfaces 214-1T and 214-2T in the direction 110. In addition, the first field plate 214 has opposite side surfaces 214S1 and 214S2 respectively connected to the upper surfaces 214-1T and 214-2T. The upper surface 214-1T of the first field plate 214 is located directly above the portion of the interlayer dielectric layer 210 between the gate structure 220 and the dielectric pattern 212. The upper surface 214-2T of the first field plate 214 is located directly above the first portion 212T1 of the top surface 212T of the dielectric pattern 212. In some embodiments, the upper surfaces 214-IT, 214-2T are not coplanar with each other. For example, in the direction 110, the upper surface 214-1T is located below the upper surface 214-2T (that is, the upper surface 214-1T is closer to the top surface 200T of the substrate 200 than the upper surface 214-2T).

As shown in FIG. 1, the side surface 214S1 of the first field plate 214 close to the gate structure 220 is located directly above the portion of the interlayer dielectric layer 210 between the gate structure 220 and the dielectric pattern 212. The side surface 214S2 of the first field plate 214 close to the drain structure 230D is located directly above dielectric pattern 212. In some embodiments, the side surface 214S2 of the first field plate 214 and the side surface 212S2 of the dielectric pattern 212 close to the drain structure 230D are not aligned with each other.

In some embodiments, the first field plate 214 may include polycrystalline silicon, a metal (such as tungsten, titanium, aluminum, copper, iron, molybdenum, nickel, platinum, the like, or a combination thereof), a metal alloy (such as nickel iron alloy (NiFe), beryllium copper alloy (BeCu), metal nitrides (such as tungsten nitride, molybdenum nitride, titanium nitride, tantalum nitride, the like, or a combination thereof), metal silicides (such as tungsten silicide, titanium silicide, cobalt silicide, nickel silicide, platinum silicide, erbium silicide, the like, or a combination thereof), metal oxides (ruthenium oxide, indium tin oxide, the like, or a combination thereof), other suitable conductive materials, or a combination thereof. In some embodiments, the first field plate 214 may be formed by a deposition process and a subsequent patterning process. The deposition process may include chemical vapor deposition (CVD), atomic layer deposition (ALD), physical vapor deposition (PVD), molecular beam deposition (MBE), plasma enhanced chemical vapor deposition (PECVD), other suitable processes, or a combination thereof.

As shown in FIG. 1, the semiconductor device 500A further includes an interlayer dielectric layer 216. The interlayer dielectric layer 216 is disposed on the interlayer dielectric layer 210. The interlayer dielectric layer 216 may extend from the source structure 230S to the drain structure 230D. In addition, the interlayer dielectric layer 216 may completely cover the dielectric pattern 212 and the first field plate 214, so that the dielectric pattern 212 and the first field plate 214 are is sandwiched between the interlayer dielectric layers 210 and 216 in the direction 110. More specifically, the interlayer dielectric layer 216 covers and is in contact with the interlayer dielectric layer 210 exposed from the dielectric pattern 212 and the first field plate 214. The interlayer dielectric layer 216 covers and is in contact with the upper surfaces 214-1T, 214-2T and the side surfaces 214S1, 214S2 of the first field plate 214. Furthermore, the interlayer dielectric layer 216 covers and is in contact with the second portion 212T2 of the top surface 212T and the side surface 212S2 of the dielectric pattern 212. As shown in FIG. 1, the first field plate 214 and the interlayer dielectric layer 216 are respectively in contact with the opposite side surface surfaces 212S1 and 212S2 of the dielectric pattern 212. As shown in FIG. 1, the source structure 230S and the drain structure 230D both penetrate through the interlayer dielectric layers 210 and 216 and the barrier layer 206 and are in contact the channel layer 204. Furthermore, the drain structure 230D and the gate electrode layer 218G located on opposite sides of the first field plate 214 are both separated from the first field plate 214 by the interlayer dielectric layer 216 in the direction 100.

In some embodiments, the interlayer dielectric layers 210 and 216 may include the same or similar materials and processes. Therefore, in some embodiments, the dielectric constant of the interlayer dielectric layer 216 is the same as the dielectric constant of the dielectric pattern 212. For example, the interlayer dielectric layer 216 and the dielectric pattern 212 are both silicon dioxide and have the same dielectric constant (k=3.9). In some embodiments, the dielectric constant of interlayer dielectric layer 216 is different from the dielectric constant of dielectric pattern 212. The dielectric constant of the interlayer dielectric layer 216 may be smaller than the dielectric constant of the dielectric pattern 212. For example, the interlayer dielectric layer 216 is silicon dioxide (k=3.9), and the dielectric pattern 212 is silicon nitride (k=7.5).

The second field plate 218 is disposed above the first field plate 214 and the dielectric pattern 212 and extends toward the drain structure 230D. The second field plate 218 covers a portion of interlayer dielectric layer 216 directly above the top surface 212T of the dielectric pattern 212. In addition, the second field plate 218 is separated from the first field plate 214 by the interlayer dielectric layer 216. In some embodiments, the first field plate 214 partially overlaps the second field plate 218. More specifically, in the direction 110, the second field plate 218 overlaps a portion of the first field plate 214 on the first portion 212T1 of the top surface 212T of the dielectric pattern 212. Moreover, the second field plate 218 does not overlap any portion of the first field plate 214 on the interlayer dielectric layer 210 between the gate structure 220 and the dielectric pattern 212. Therefore, the second field plate 218 is closer to the drain structure 230D than the first field plate 214. Furthermore, in the direction 110, the first field plate 214 and the second field plate 218 both overlap the source metal layer (not shown) of the source structure 230S.

In some embodiments, the second field plate 218 is conformally formed on the interlayer dielectric layer 210, the dielectric pattern 212, and the first field plate 214. Therefore, the second field plate 218 has a stepped shape in the cross-sectional view shown in FIG. 1. In this embodiment, the number of steps of the stepped second field plate 218 is 2. Therefore, the second field plate 218 has two upper surfaces 218-1T, 218-2T in the direction 110. In addition, the second field plate 218 has opposite side surfaces 218S1, 218S2 connected to the upper surfaces 218-1T, 218-2T respectively. The upper surface 218-1T of the second field plate 218 is located directly above the first portion 212T1 of the top surface 212T of the dielectric pattern 212 (or the upper surface 214-2T of the first field plate 214). The upper surface 218-2T of the second field plate 218 is located directly above the second portion 212T2 of the top surface 212T of the pattern 212. In some embodiments, the upper surfaces 218-1T, 218-2T are not coplanar with each other. For example, in the direction 110, the upper surface 218-1T is located above the upper surface 218-2T (that is, the upper surface 218-2T is closer to the top surface 200T of the substrate 200 than the upper surface 218-1T).

As shown in FIG. 1, the side surface 218S1 of the second field plate 218 close to the gate structure 220 is located directly above the first portion 212T1 of the top surface 212T of the dielectric pattern 212 (or the top surface 214-2T of the first field plate 214). In addition, the side surface 218S2 of the second field plate 218 close to the drain structure 230D is located directly above the second portion 212T2 of the top surface 212T of the dielectric pattern 212. In some embodiments, the second field plate 218 is located directly over dielectric pattern 212 and covers a portion of the dielectric pattern 212. Accordingly, the opposite side surfaces 218S1, 218S2 of the second field plate 218 are not aligned with the corresponding side surfaces 212S1, 212S2 of the dielectric pattern 212. Moreover, in the direction 100, the side surface 218S2 of the second field plate 218 close to the drain structure 230D is closer to the drain structure 230D than the side surface 214S2 of the first field plate 214 close to the drain structure 230D. In addition, the side surface 230S-S of the source metal layer of the source structure 230S close to the drain structure 230D is closer to the drain structure 230D than the side surface 218S2 of the second field plate 218.

In some embodiments, the first field plate 214 and the second field plate 218 may include the same or similar materials and processes. In some embodiments, the second field plate 218 may be formed simultaneously with the gate electrode layer 218G.

As shown in FIG. 1, the semiconductor device 500A further includes an interlayer dielectric layer 226. The interlayer dielectric layer 226 is disposed on the interlayer dielectric layer 216. The interlayer dielectric layer 226 entirely covers the source structure 230S, the drain structure 230D and extends from the source structure 230S to the drain structure 230D. Furthermore, the drain structure 230D is separated from the second field plate 218 by the interlayer dielectric layer 226 in the direction 100. In some embodiments, the interlayer dielectric layers 210, 216, 226 may include the same or similar materials and processes. Therefore, in some embodiments, the dielectric constant of the interlayer dielectric layer 226 is the same as from the dielectric constant of the dielectric pattern 212. For example, the interlayer dielectric layer 226 and the dielectric pattern 212 are silicon dioxide. In addition, the interlayer dielectric layer 226 and the dielectric pattern 212 have the same dielectric constant (k=3.9). In some embodiments, the dielectric constant of the interlayer dielectric layer 226 is different from the dielectric constant of the dielectric pattern 212. The dielectric constant of the interlayer dielectric layer 226 may be smaller than the dielectric constant of the dielectric pattern 212. For example, the interlayer dielectric layer 226 is silicon dioxide (k=3.9), and the dielectric pattern 212 is silicon nitride (k=7.5). In some embodiments, the interlayer dielectric layer 226 may be a single-layer structure or a multi-layer structure.

In some embodiments, the first field plate 214 and the second field plate 218 of the semiconductor device 500A extend toward the drain structure 230D in the direction 100 and are electrically connected to the source structure 230S. Therefore, the first field plate 214 and the second field plate 218 may also serve as the source field plates 214 and 218, which can effectively reduce the surface electric field (REduced SURface Field, or RESURF). Furthermore, the first field plate 214 is a stepped source field plate conformally formed on the interlayer dielectric layer 210 and the dielectric pattern 212. The second field plate 218 is a stepped source field plate conformally formed on the interlayer dielectric layer 210, the dielectric pattern 212 and the first field plate 214. Therefore, a multi-layer (e.g., two-layer) field plate structure can be fabricated by a single-layer field plate process. The first field plate 214 and the second field plate 218 in accordance with some embodiments of the disclosure may have the electric field redistribution ability comparable to the multi-layer field plate structure while saving the fabrication cost of a single-layer field plate structure (such as the fabrication cost of the photomask). Therefore, the number of field plates can be reduced, and the capacitance generated between the gate electrode and the drain region can be reduced. The first field plate 214 and the second field plate 218 can avoid large electric field peak induced at the edge of the drain electrode layer (for example, at the side surface 214S2 of the first field plate 214 close to the drain structure 230D or the side surface 218S2 of the second field plate 218 close to the drain structure 230D), thereby reducing the drain-to-source on resistance (R_{DS-ON}) and increasing the breakdown voltage of the high electron mobility transistor device. In addition, the first field plate 214 and the second field plate 218 are disposed on the different interlayer dielectric layers 210 and 216. Therefore, the distance between each field plate and the barrier layer 206 can be adjusted to further increase the breakdown voltage of the high electron mobility transistor (HEMT) device.

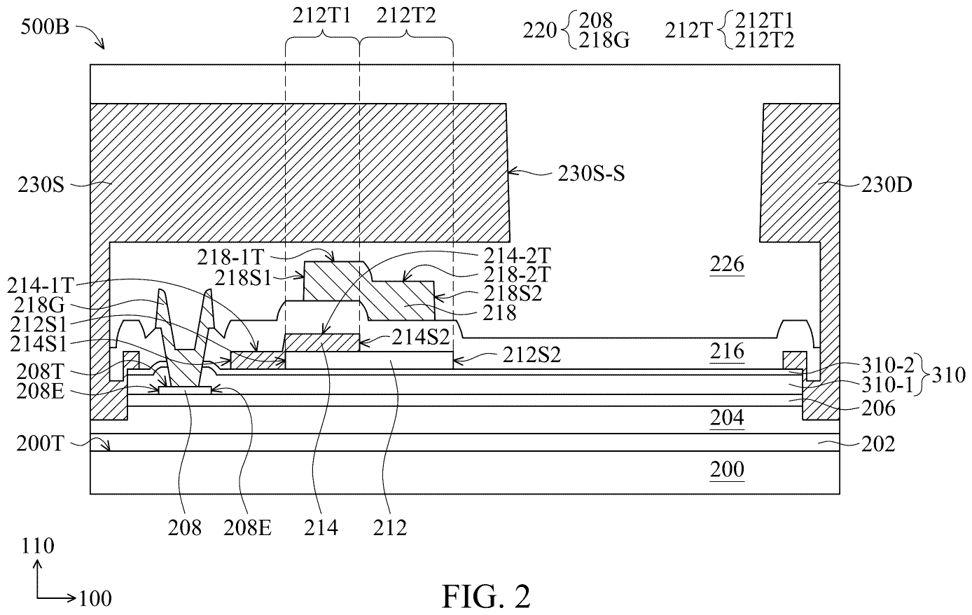

FIG. 2 is a schematic cross-sectional view of a semiconductor device 500B in accordance with some embodiments of the disclosure, in which reference numbers that are the same or similar to those in FIG. 1 denote the same or similar elements. As shown in FIG. 2, the difference between the semiconductor device 500B and the semiconductor device 500A is at least that the semiconductor device 500B further includes an interlayer dielectric layer 310 disposed on the barrier layer 206 and partially covering the gate structure 220. The difference between the interlayer dielectric layer 310 of the semiconductor device 500B and the interlayer dielectric layer 210 of the semiconductor device 500A is that the interlayer dielectric layer 310 is a multi-layer structure formed of dielectric materials with different dielectric constants.

In some embodiments, interlayer dielectric layer 310 includes a plurality of dielectric sub-layers. For example, the interlayer dielectric layer 310 includes two dielectric sub-layers 310-1 and 310-2. However, the present disclosure is not limited to the disclosed embodiments. As shown in FIG. 2, the dielectric sub-layer 310-1 is disposed on the gate layer 208 of the gate structure 220, and the dielectric sub-layer 310-2 is disposed on the dielectric sub-layer 310-1. Furthermore, the dielectric sub-layers 310-1 and 310-2 are adjacent to different portions of the sidewalls of the gate electrode layer 218G. The dielectric pattern 212, the first field plate 214 and the interlayer dielectric layer 216 are in contact with the dielectric sub-layer 310-2 and are separated from the dielectric sub-layer 310-1 by the dielectric sub-layer 310-2.

The dielectric sub-layer 310-1 has a first dielectric constant. The dielectric sub-layer 310-2 has a second dielectric constant. In some embodiments, the second dielectric constant is different than the first dielectric constant. The second dielectric constant of the dielectric sub-layer 310-2 in contact with the dielectric pattern 212 may be greater than the first dielectric constant of the dielectric sub-layer 310-1 and higher than the dielectric constant of silicon dioxide (k=3.9). In other words, dielectric sub-layer 310-2 may be formed of a high-k dielectric material. For example, the dielectric sub-layer 310-1 may be silicon dioxide (k=3.9). In addition, the dielectric sub-layer 310-2 can be silicon nitride (k=7.5).

In some embodiments, the second dielectric constant of dielectric sub-layer 310-2 is different from the dielectric constant of dielectric pattern 212. The second dielectric constant of the dielectric sub-layer 310-2 may be greater than the dielectric constant of the dielectric pattern 212. For example, the dielectric pattern 212 may be silicon dioxide (k=3.9). In addition, the dielectric sub-layer 310-2 may be silicon nitride (k=7.5).

In some embodiments, the semiconductor device 500B has the advantages of the semiconductor device 500A. In addition, since the interlayer dielectric layer 310 of the semiconductor device 500B includes the dielectric sub-layer 310-2 with a high dielectric constant, which can withstand high electric fields. Therefore, the electric field distribution on the surface of the semiconductor device 500B can be relatively uniform. For example, the electric field peak at the edge 208E of the gate layer 208 close to the drain structure 230D. Furthermore, the dielectric pattern 212 and the underlying dielectric sub-layer 310-2 in contact with each other may be formed of different dielectric materials. Therefore, the dielectric sub-layer 310-2 may serve as an etching stop layer for the dielectric pattern 212 during the patterning process (including lithography and etching processes) for forming the dielectric pattern 212. In addition, the thickness of the interlayer dielectric layer 310 can be precisely controlled. Therefore, the figure of merit (FOM) of the semiconductor device 500B (for example, the pinch-off voltage of the semiconductor device 500B) can be further improved.

Embodiments of the disclosure provide a semiconductor device, such as a high electron mobility transistor (HEMT) device. In some embodiments, the semiconductor device includes a dielectric pattern disposed on a portion of the first interlayer dielectric layer (e.g., interlayer dielectric layer 210) between the gate structure and the drain structure, so that the first field plate and the second field plate above the first field plate of the semiconductor device are stepped source field plates. Therefore, the multi-layer (e.g., two-layer) field plate structure can be fabricated by a single-layer field plate process. The (2-step) stepped field plate may have the electric field redistribution ability comparable to the multi-layer field plate structure while saving the fabrication cost of a single-layer field plate structure (such as the fabrication cost of the photomask), and avoid large electric field peaks. Through the arrangement of stepped source field plates, the number of field plates can be reduced, and the capacitance generated between the gate electrode and the drain region can be reduced. Furthermore, the distance between each of the field plates and the barrier layer can be adjusted, thereby reducing the drain-to-source on resistance (R_{DS-ON)} and increasing the breakdown voltage of the high electron mobility transistor device. In some embodiments, the dielectric pattern of the semiconductor device and the underlying first interlayer dielectric layer are formed of dielectric materials with different dielectric constants. For example, the first interlayer dielectric layer may be formed of silicon dioxide, and the dielectric pattern may be formed of a high-k dielectric material, such as silicon nitride. Alternatively, the first interlayer dielectric layer of the semiconductor device includes a plurality of dielectric sub-layers. The dielectric pattern and the underlying dielectric sub-layer in contact with each other are formed of dielectric materials with different dielectric constants. For example, the dielectric pattern may be formed of silicon dioxide and the dielectric sub-layer may be formed of a high-k dielectric material such as silicon nitride. The dielectric pattern or the dielectric sub-layer having high dielectric constant can make the electric field distribution on the surface of the semiconductor device more uniform. Furthermore, during the etching process for forming the dielectric pattern, the first interlayer dielectric layer or the dielectric sub-layer having a high dielectric constant may serve as an etching stop layer for the etching process. Therefore, the variation of the thickness of the first interlayer dielectric layer cause by the etching process is eliminated. The figure of merit (FOM) of the semiconductor device is improved accordingly.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a gate structure disposed on the substrate;
a first interlayer dielectric layer disposed on the substrate and partially covering the gate structure;
a source structure and a drain structure disposed on the substrate and located on opposite sides of the gate structure;
a dielectric pattern disposed on the first interlayer dielectric layer between the gate structure and the drain structure;
a first field plate disposed on the substrate and covering the dielectric pattern, as well as covering the first interlayer dielectric layer between the gate structure and the dielectric pattern; and
a second field plate disposed above the first field plate and the dielectric pattern and extending toward the drain structure.

2. The semiconductor device as claimed in claim 1, wherein the dielectric pattern and the gate structure are separated from each other by a first distance in a first direction, the dielectric pattern and the drain structure are separated from each other by a second distance, and the first distance is less than the second distance.

3. The semiconductor device as claimed in claim 1, wherein the first field plate comprises:
a first upper surface located directly above the first interlayer dielectric layer between the gate structure and the dielectric pattern; and
a second upper surface located directly above a first portion of a top surface of the dielectric pattern, wherein the first upper surface and the second upper surface are not coplanar.

4. The semiconductor device as claimed in claim 3, wherein the first upper surface is below the second upper surface.

5. The semiconductor device as claimed in claim 3, wherein the first field plate is in contact with the first portion of the top surface of the dielectric pattern.

6. The semiconductor device as claimed in claim 3, wherein a first side surface of the first field plate close to the drain structure is located directly above the dielectric pattern.

7. The semiconductor device as claimed in claim 3, wherein a second side surface of the second field plate close to the drain structure is located directly above a second portion of the top surface of the dielectric pattern, wherein the first portion and the second portion are adjacent to each other and are different portions of the top surface of the dielectric pattern.

8. The semiconductor device as claimed in claim 7, wherein the second field plate comprises:
a third upper surface located directly above the first portion of the top surface of the dielectric pattern; and
a fourth upper surface located directly above the second portion of the top surface of the dielectric pattern, wherein the third upper surface is located above the fourth upper surface.

9. The semiconductor device as claimed in claim 1, wherein the first interlayer dielectric layer and the dielectric pattern comprise different materials.

10. The semiconductor device as claimed in claim 1, wherein the first interlayer dielectric layer comprises:
a first dielectric sub-layer disposed on a gate layer of the gate structure, wherein the first dielectric sub-layer has a first dielectric constant; and
a second dielectric sub-layer disposed on the first dielectric sub-layer, wherein the second dielectric sub-layer has a second dielectric constant that is different from the first dielectric constant.

11. The semiconductor device as claimed in claim 10, wherein the second dielectric constant is greater than the first dielectric constant.

12. The semiconductor device as claimed in claim 10, wherein the dielectric pattern has a third dielectric constant, and the second dielectric constant is different from the third dielectric constant.

13. The semiconductor device as claimed in claim 12, wherein the second dielectric constant is greater than the third dielectric constant.

14. The semiconductor device as claimed in claim 12, wherein the third dielectric constant is equal to the first dielectric constant.

15. The semiconductor device as claimed in claim 1, wherein the first field plate partially overlaps the second field plate.

16. The semiconductor device as claimed in claim 1, wherein the first field plate and the second field plate are electrically connected to the source structure.

17. The semiconductor device as claimed in claim 1, wherein in a cross-sectional view, the first field plate has a stepped shape.

18. The semiconductor device as claimed in claim 1, further comprising:
a second interlayer dielectric layer disposed on the first interlayer dielectric layer and covering the dielectric pattern and the first field plate.

19. The semiconductor device as claimed in claim 18, wherein the first field plate and the second interlayer dielectric layer are in contact with opposite side surfaces of the dielectric pattern.

20. The semiconductor device as claimed in claim 18, further comprising:
a buffer layer located on the substrate;
a channel layer located on the buffer layer; and
a barrier layer located on the channel layer, wherein the gate structure is disposed on the barrier layer, wherein the source structure and the drain structure both penetrate the second interlayer dielectric layer, and wherein the first interlayer dielectric layer and the barrier layer and are in contact with the channel layer.
